(19) United States
(12) Patent Application Publication
(10) Pub. No.: US 2024/0213079 A1
(43) Pub. Date: Jun. 27, 2024

(54) SUBSTRATE HEATER AND SUBSTRATE PROCESSING APPARATUS INCLUDING THE SAME

(71) Applicant: SEMES CO., LTD., Cheonan-si (KR)

(72) Inventors: Jumi Lee, Seoul (KR); Jaeoh Bang, Seoul (KR); Minyoung KIM, Hwaseong-si (KR)

(21) Appl. No.: 18/515,867

(22) Filed: Nov. 21, 2023

(30) Foreign Application Priority Data
Dec. 26, 2022 (KR) 10-2022-0185007

(51) Int. Cl. H01L 21/687; H01L 21/67

(52) U.S. Cl. CPC H01L 21/68757; H01L 21/67109; H01L 21/68742; H01L 21/6875

(57) ABSTRACT

Provided is a substrate heater including a support plate configured to be loaded with a substrate, an insulating layer arranged under the support plate, and a heating portion arranged under the insulating layer and configured to heat the support plate, wherein the insulating layer includes a plurality of layers, wherein at least two of the plurality of layers of the insulating layer have different thermal expansion coefficients from each other.

### CROSS-REFERENCE TO RELATED APPLICATION

This application is based on and claims priority under 35 U.S.C. § 119 to Korean Patent Application No. 10-2022-0185007, filed on Dec. 26, 2022, in the Korean Intellectual Property Office, the disclosure of which is incorporated by reference herein in its entirety.

### BACKGROUND

### 1. Field

The disclosure relates to a substrate heater and a substrate processing apparatus including the substrate heater, and more particularly, to a substrate heater which suppresses bending of a support plate and a substrate processing apparatus including the substrate heater.

### 2. Description of the Related Art

Substrate heating apparatuses may be used to heat a semiconductor substrate, form on the substrate a semiconductor thin film to be used in a liquid substrate or a circuit substrate, and form a resist film on the substrate by drying and baking a resist liquid applied on the substrate. Substrate heating apparatuses may be used, for example, for heating a semiconductor substrate in a process of forming the semiconductor substrate and for etching and baking a resist film in a process of manufacturing semiconductor devices. Recently, according to the tendency of miniaturization and high productivity in manufacturing semiconductors, reducing the time for substrate processing has been required. To reduce the time required to process a substrate, substrate heaters capable of rapidly changing the temperature of substrate are needed.

In addition to operating systems, the processing speed of each process has been considered as a major factor in increasing the productivity in manufacturing semiconductors. To keep up with such a trend, there have been efforts to raise the PEB temperature change speed in photo track equipment to increase the productivity. Thin PEB heaters have been require to enable fast temperature change according to a type of a photoresist.

### SUMMARY

Provided is a substrate heater including a support plate having a thin thickness without any bending, and a substrate processing apparatus including the substrate heater.

Provided is a substrate heater capable of securing great mechanical reliability through a support plate including silicon carbide and a substrate processing apparatus including the substrate heater.

The object which the technical ideas of the disclosure seek to achieve is not limited to the foregoing, and other objects may be clearly understood by a person skilled in the art from the description below.

Additional aspects will be set forth in part in the description which follows and, in part, will be apparent from the description, or may be learned by practice of the presented embodiments of the disclosure.

According to an aspect of the disclosure, a substrate heater includes a support plate configured to be loaded with a substrate, an insulating layer arranged under the support plate, and a heating portion arranged under the insulating layer and configured to heat the support plate, wherein the insulating layer includes a plurality of layers, and at least two of the plurality of layers of the insulating layer have different thermal expansion coefficients from each other.

A first layer and a second layer of the insulating layer may be stacked alternately, and a thermal expansion coefficient of the first layer and a thermal expansion coefficient of the second layer may be different from a thermal expansion coefficient of the support plate.

The insulating layer may include an even number of layers.

The thermal expansion coefficient of the first layer may be greater than the thermal expansion coefficient of the support plate, and the thermal expansion coefficient of the second layer may be less than the thermal expansion coefficient of the support plate.

An average thermal expansion coefficient of the insulating layer may be identical to a thermal expansion coefficient of the support plate.

The thermal expansion coefficient of the first layer may be about 4.5e⁻⁶/° C. to about 8.5e⁻⁶/° C., and the thermal expansion coefficient of the second layer may be about 2.5e⁻⁶/° C. to about 3.5e⁻⁶/° C.

A thickness of the insulating layer may be about 40 μm to about 200 μm.

A withstand voltage of the insulating layer may be about 1.5 kV to about 5 kV.

A thickness of each of the plurality of layers of the insulating layer may be about 10 μm to about 25 μm.

A thickness of the support plate may be about 0.5 mm to about 3 mm.

The support plate may further include an oxide layer on a lower surface of the support layer.

The insulating layer may include a first layer, a second layer, and a third layer, a thermal expansion coefficient of the first layer may be greater than a thermal expansion coefficient of the support plate, a thermal expansion coefficient of the second layer may be less than the thermal expansion coefficient of the support plate, and a thermal expansion coefficient of the third layer may be less than the thermal expansion coefficient of the first layer and may be greater than the thermal expansion coefficient of the second layer.

According to another aspect of the disclosure, a substrate processing apparatus includes a chamber, a substrate heater arranged in the chamber, having a through hole extending from an upper surface to a lower surface thereof, and including a support plate, an insulating layer, and a heating portion, a support pin arranged on an upper surface of the support plate and configured to support a substrate, a lifting pin configured to lift and lower the substrate through the through hole, and at least one power source connected to the substrate heater, wherein the insulating layer is arranged under the support plate and includes a plurality of layers, at least two of the plurality of layers have different thermal expansion coefficients from each other, and the heating portion is arranged under the insulating layer.

The heating portion may include a heating line on an upper surface thereof, and a heat amount transmitted to the support plate may increase as a distance to a center of the upper surface decreases.

The heating portion may include a plurality of heating lines on the upper surface thereof. The plurality of heating lines may respectively be connected to different power sources from each other, and an intensity of power of the power sources may increase as a distance between the plurality of heating lines respectively connected to the power sources and a center of the heating portion decreases.

A lower surface of the support plate may be a flat surface, and the upper surface of the support plate may be an upwardly convex curved surface.

In the insulating layer, a first layer having a thermal expansion coefficient greater than a thermal expansion coefficient of the support plate and a second layer having a thermal expansion coefficient less than the thermal expansion coefficient of the support layer may be alternately stacked, at least a part of the first layer may be in contact with the support plate, and at least a part of the second layer may be in contact with the heating portion.

A thickness of the insulating layer may be about 40 μm to about 200 μm, and a withstand voltage of the insulating layer may be about 1.5 kV to about 5 kV.

A first layer, a second layer, and a third layer of the insulating layer may be stacked alternately, a thermal expansion coefficient of the first layer may be greater than a thermal expansion coefficient of the support plate, a thermal expansion coefficient of the second layer may be less than the thermal expansion coefficient of the support plate, and a thermal expansion coefficient of the third layer may be identical to the thermal expansion coefficient of the support plate.

The substrate heater may further include an oxide layer between the support plate and the insulating layer.

According to another aspect of the disclosure, a substrate processing apparatus includes a chamber, a substrate heater arranged in the chamber, having a through hole extending from an upper surface to a lower surface thereof, and including a support plate, an insulating layer, and a heating portion, a support pin arranged on an upper surface of the support plate and configured to support a substrate, a lifting pin configured to lift and lower the substrate through the through hole, and at least one power source arranged in the chamber and connected to the substrate heater, wherein the support plate includes silicon carbide, the insulating layer is arranged under the support plate, and includes an even number of layers, wherein a first layer having a thermal expansion coefficient greater than a thermal expansion coefficient of the support plate and a second layer having a thermal expansion coefficient less than the thermal expansion coefficient of the support layer are alternately stacked, a thickness of the first layer is about 10 μm to about 25 μm, and a thickness of the second layer is about 10 μm to about 25 μm.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are schematic cross-sectional views of a substrate heater according to an embodiment;

FIG. 2 is an enlarged view of part II of FIG. 1A;

FIG. 3 is a schematic plan view of a heating portion of FIG. 1A;

FIG. 4 is a schematic cross-sectional view of a substrate heater according to an embodiment;

FIG. 5 is a schematic cross-sectional view of a substrate heater according to an embodiment;

FIG. 6 is a schematic cross-sectional view of a substrate processing apparatus according to an embodiment;

FIG. 7 is a schematic cross-sectional view of a substrate processing apparatus according to an embodiment;

FIG. 8 is a schematic cross-sectional view of a substrate processing apparatus according to an embodiment;

FIG. 9 is a schematic cross-sectional view of a substrate processing apparatus according to an embodiment; and

FIGS. 10A to 10G are cross-sectional views schematically illustrating a process of manufacturing a substrate heater according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

General terms which are currently used widely have been selected for use in consideration of their functions in embodiments; however, such terms may be changed according to an intention of a person skilled in the art, precedents, advent of new technologies, etc. Also, in certain cases, the applicant may arbitrarily select terms, and in such case, meanings of the terms will be described in detail in corresponding sections. Accordingly, the terms used in the embodiments should be defined based on their meanings and overall descriptions of the embodiments, not simply by their names.

As the disclosure allows for various changes and numerous embodiments, exemplary embodiments will be illustrated in the drawings and described in detail in the written description. However, this is not intended to limit embodiments to particular modes of practice, and it is to be appreciated that all changes, equivalents, and substitutes that do not depart from the spirit and technical scope of the disclosure are encompassed in embodiments. The terms used in the specification are merely used to describe embodiments, and are not intended to limit the embodiments.

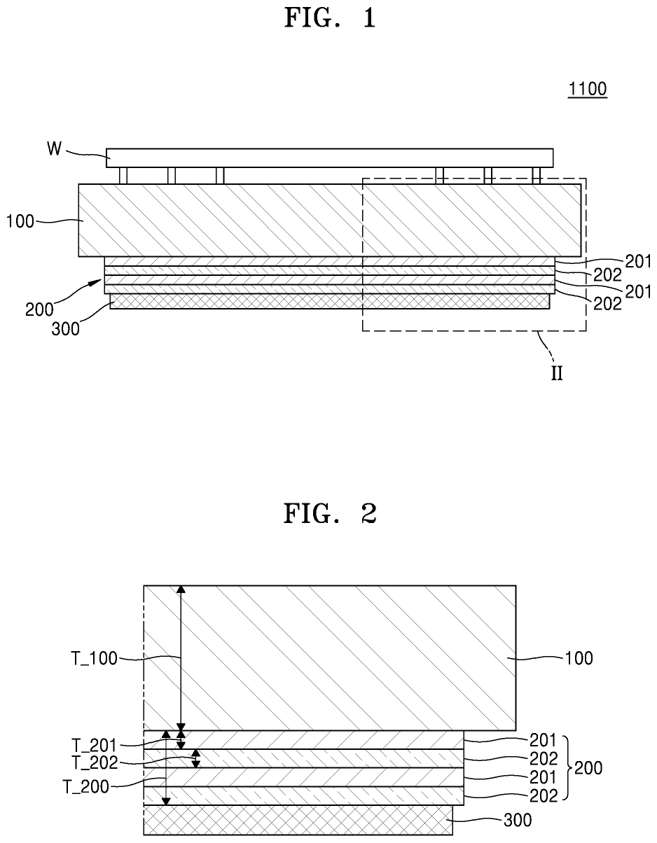

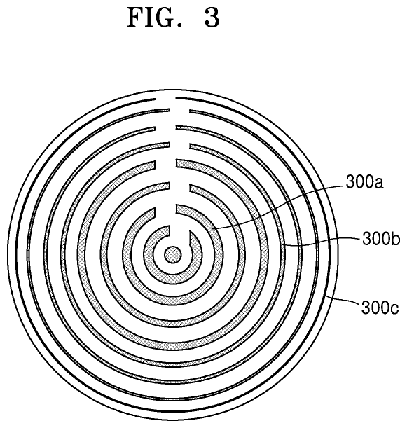

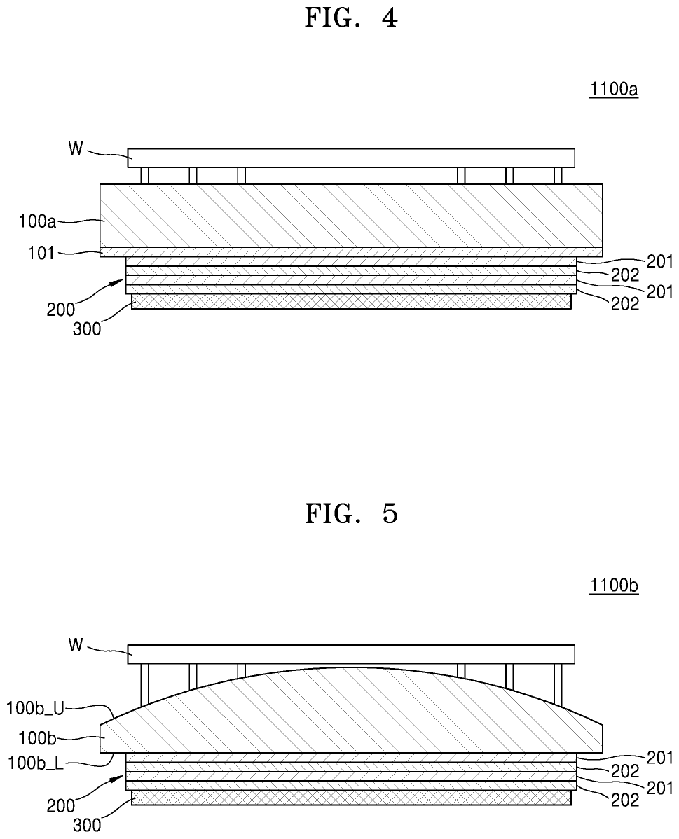

FIGS. 1A and 1B are schematic cross-sectional views of a substrate heater according to an embodiment. FIG. 2 is an enlarged view of part II of FIG. 1A. FIG. 3 is a schematic plan view of a heating portion of FIG. 1A.

Referring to FIGS. 1A to 3, a substrate heater 1100 may include a support plate 100, an insulating layer 200, and a heating portion 300.

The support plate 100 of the substrate heater 1100 may be configured to be loaded with a substrate W. That is, the substrate W may be loaded on the support plate 100. According to some embodiments, the support plate 100 may heat up the substrate W to a set temperature. According to some embodiments, the support plate 100 may support and fix the substrate W when manufacturing processes of various semiconductor devices are performed on the substrate W and may maintain the temperature of the substrate W at a set temperature.

A material constituting the support plate 100 may include silicon carbide. The support plate 100 may include a semiconductor material. In some embodiments, a thickness T_100 of the support plate 100 may be about 0.5 mm to about 3 mm. The thickness of the support plate 100 may not exceed 4 mm.

The substrate heater 1100 according to an embodiment may include silicon carbide as a constituent of the support plate 100 and may have a more stable mechanical reliability, compared to a support plate including silicon. That is, the substrate heater 1100 may prevent damage and scratches due to an external environment.

The insulating layer 200 of the substrate heater 1100 may be arranged under the support plate 100. The insulating layer 200 may consist of a plurality of layers (201 and 202). For example, the insulating layer 200 may include the plurality of layers (201 and 202) alternately stacked in a direction perpendicular to a lower surface of the support plate 100. The insulating layer 200 having a multi-layer structure may be arranged under the support plate 100.

A coefficient of thermal expansion (CTE) may represent a change in length (or volume) in relation to temperature change. A CTE of length (i.e., linear CTE) may be represented by ΔL/(L·ΔT) where ΔL represents a change in length, L represents an initial length, and ΔT represents a change in temperature.

The insulating layer 200 may include the plurality of layers (201 and 202). That is, each layer of the insulating layer 200 may have different changes in volume and length according to a temperature change. At least tow of the plurality of layers (201 and 202) of the insulating layer 200 may have different CTEs from each other. In some embodiments, a CTE of each of the plurality of layers (201 and 202) may be different from a CTE of the support plate 100.

In some embodiments, an average CTE of the insulating layer 200 may be substantial identical to the CTE of the support plate 100. The average CTE of the insulating layer 200 may refer to an average value of a CTE of each of the plurality of layers (201 and 202) multiplied by a thickness of each layer (T_201 and T202) and then divided by a thickness of the insulating layer 200. That is, (average CTE of insulating layer)=(CTE of each layer)×(thickness of each layer)/(thickness of insulating layer). As the average CTE of the insulating layer 200 is substantially identical to the CTE of the support plate 100, physical deformation of the support plate 100 which may occur during formation of the insulating layer 200 may be suppressed.

In some embodiments, in the insulating layer 200, a first layer 201 and a second layer 202 may be alternately stacked. In other words, the insulating layer 200 may include the first layer 201 and the second layer 202 which are alternately stacked and may consist of four or more layers. That is, in the insulating layer 200, the first layer 201 and the second layer 202 may be alternately stacked, forming a plurality of layers.

In some embodiments, an even number of the layers (201 and 202) may be provided. That is, the plurality of layers (201 and 202) may be 2n layers. Here, n is an integer greater than or identical to 1. The plurality of layers (201 and 202) may be an even number of layers including the first layer(s) 201 and the second layer(s) 202 which are alternately stacked. That is, the plurality of layers (201 and 202) may include the same number of first layers 201 as the second layers 202. In some embodiments, the plurality of layers (201 and 202) may have six layers including three first layers 201 and three second layers 202.

In some embodiments, the first layer 201 and the second layer 202 may have different CTEs from each other. More specifically, a CTE of the first layer 201 may be greater than a CTE of the support plate 100, and a CTE of the second layer 202 may be less than the CTE of the support plate 100. In other words, the first layer 201 may have relatively great changes in length and volume according to a temperature change, compared to the support plate 100, and the second layer 202 may have relatively less changes in length and volume according to a temperature change, compared to the support plate 100.

In some embodiments, the support plate 100 may include silicon carbide and have a CTE of 4e⁻⁶/° C. The CTE of the first layer 201 may be 4.5e⁻⁶/° C. to 8.5e⁻⁶/° C., which is greater than the CTE of the support plate 100. The CTE of the second layer 202 may be 2.5e⁻⁶/° C. to 3.5e⁻⁶/° C., which is less than the CTE of the support plate 100.

In some embodiments, the first layer 201 of the insulating layer 200 may be in contact with a lower surface of the support plate 100, and the second layer 202 may be arranged under the first layer 201. In other words, the lower surface of the support plate 100 may be in contact with the first layer 201, and the support plate 100 and the second layer 202 may be apart from each other with the first layer 201 arranged therebetween. Although FIG. 1A illustrates that the first layer 201 is in contact with the support plate 100, the disclosure is not limited thereto, and the second layer 202 may be in contact with the support plate 100. That is, a layer having a relatively smaller CTE than the support plate 100 may be in contact with the support plate 100.

In a stacked body to which material layers having different CTEs from each other are attached, when temperatures rises, an end portion of a material layer having a relatively great CTE may be bent towards a material layer having a relatively small CTE. In other words, as the change in volume according to the temperature change is greater in the material layer having a relatively great CTE, the end portion of the material layer having a relatively great CTE may be bent towards the material layer having a relatively small CTE.

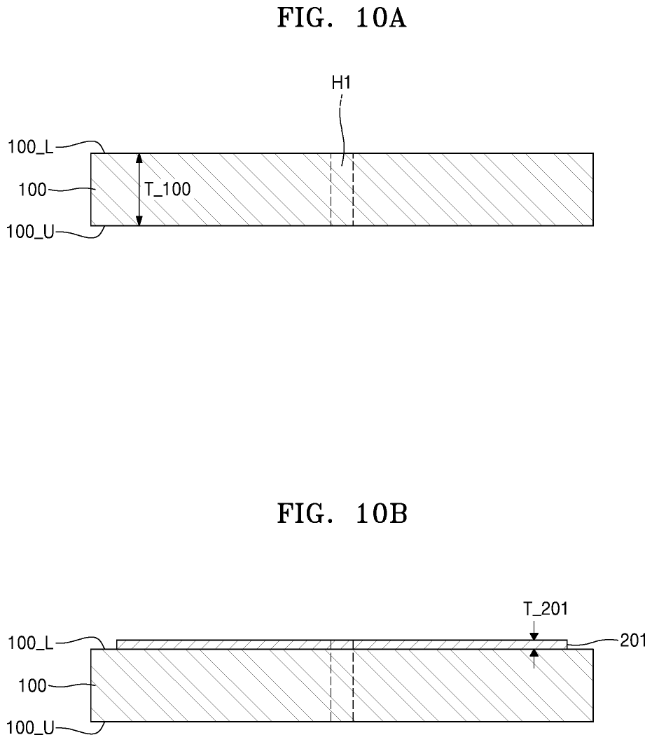

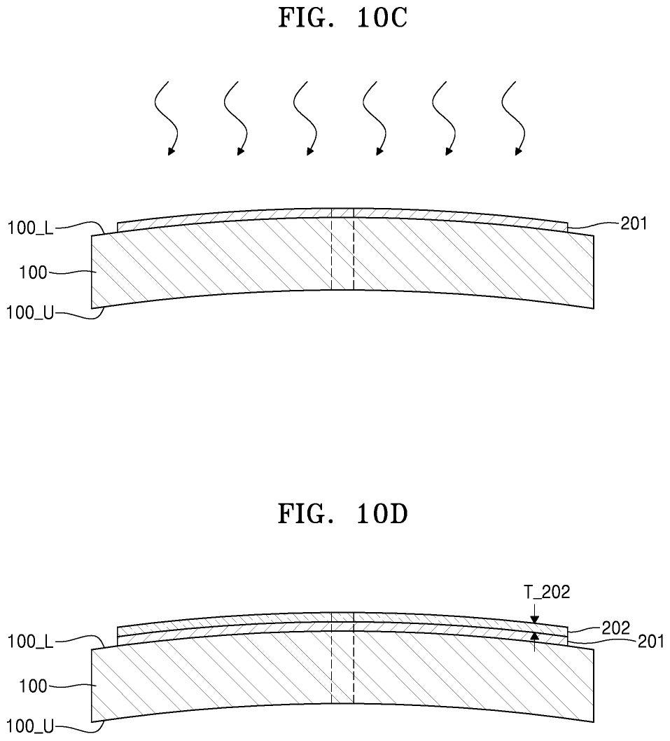

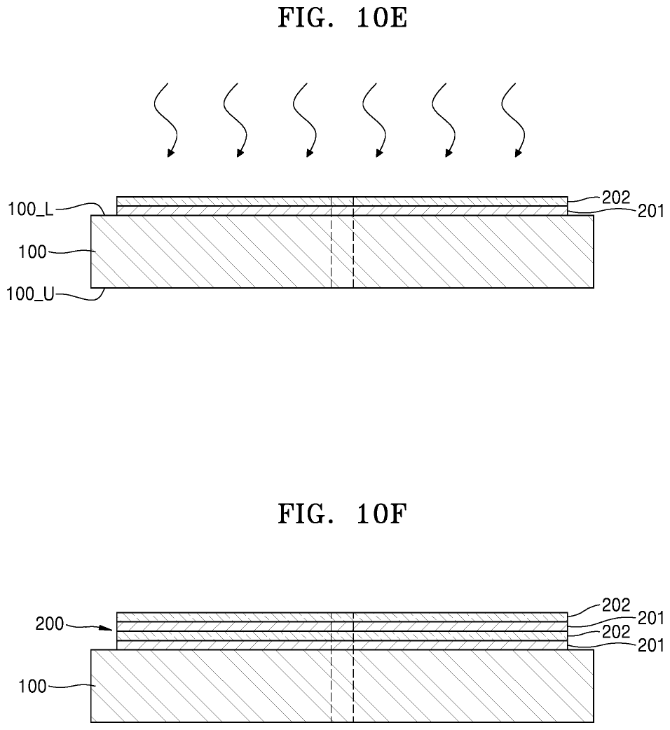

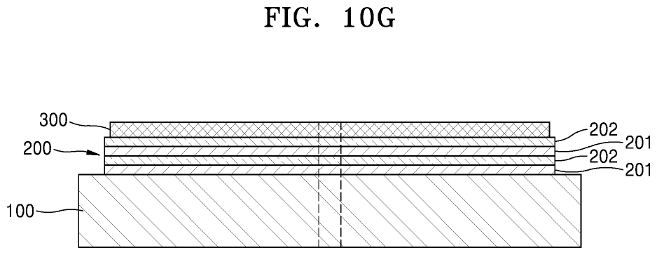

In some embodiments, when the first layer 201 and the support plate 100, which have different CTEs from each other, are in contact with each other, and the temperature rises, an end portion of the first layer 201 may be bent towards the support plate 100. Accordingly, the support plate 100 may be bent. Then, after attaching the second layer 202 having a small CTE to the first layer 201, when the temperature rises, an end portion of the support plate 100 may be bent towards the second layer 202. As such, the support plate 100 may be bent in opposite directions by the first layer 201 and the second layer 202, and finally have a flat shape without a bend. For example, the stress provided by the first layer 201 to the support plate 100 due to temperature change may offset the stress provided by the second layer 202 to the support plate 100 due to temperature change. The method of forming the insulating layer 200 on the support plate 100 is to be described later in relation to FIGS. 10A to 10G.

In some embodiments, the thickness of each of the plurality of layers (201 and 202) may be about 10 μm to about 15 μm. In some embodiments, a thickness T_201 of the first layer 201 may be about 10 μm to about 15 μm, and a thickness T_202 of the second layer 202 may be about 10 μm to about 15 μm. Although FIG. 2 illustrates that the layers have the same thickness, the disclosure is not limited thereto, and the layers may have different thicknesses from each other. More specifically, the thickness of each layer may vary according to a CTE.

Referring to FIG. 1B, an insulating layer 200a may include a first layer 201, a second layer 202, and a third layer 203.

More specifically, the insulating layer 200a may include a plurality of stacked layers including the first layer 201, the second layer 202, and the third layer 203. In some embodiments, the insulating layer 200a may have six layers including the first layer 201, the second layer 202, and the third layer 203, which are alternately stacked, or may have three stacked layers including one first layer 201, one second layer 202, and one third layer 203.

The first layer 201 to third layer 203 may have different CTEs from each other. In some embodiments, the CTE of the first layer 201 may be greater than the CTE of the support plate 100, the CTE of the second layer 202 may be less than the CTE of the support plate 100, and the CTE of the third layer 203 may be substantially identical to the CTE of the support plate 100. In other words, the CTE of the third layer 203 may be between the CTE of the first layer 201 and the CTE of the second layer 202.

In some embodiments, the first layer 201 may be in contact with the lower surface of the support plate 100, and the second layer 202 and the third layer 203 may be stacked under the first layer 201 in this order. In addition, the third layer 203 may be in contact with the lower surface of the support plate 100, and the first layer 201 and the second layer 202 may be stacked under the third layer 203 in this order. That is, the stacking order among the first layer 201 to third layer 203 is not limited to FIG. 1B.

A substrate heater 1100′ according to an embodiment may suppress physical deformation of the support plate 100 through the first layer 201 and the second layer 202, which have different CTEs from the CTE of the support plate 100, and adjust the thickness of the insulating layer 200a through the third layer 203, which has substantially the same CTE as the CTE of the support plate 100.

The heating portion 300 of the substrate heater 1100 may be arranged under the insulating layer 200. The heating portion 300 may heat the support plate 100. For example, the heating portion 300 may include an insulating sheet and an electric resistant heating line arranged in the insulating sheet. That is, the heating portion 300 may generate heat and raise temperature of the support plate 100. In some embodiments, the heat generated by the heating portion 300 may be transmitted to the support plate 100 through the insulating layer 200 by conduction. That is, the heating portion 300 may transmit the heat to the support plate 100 from the lower surface of the insulating layer 200 through the insulating layer 200.

In some embodiments, the heating portion 300 may include heating lines (300a, 300b, and 300c). The heating lines (300a, 300b, and 300c) may be a device in which heat is generated due to high electric resistance when a current flows. The heating portion 300 may include an electrode pad on its lower surface and supply power to the heating lines (300a, 300b, and 300c). The heating portion 300 may emit heat through the heating liens (300a, 300b, and 300c) and heat the support plate 100.

In some embodiments, the area or width (e.g., width according to a radial direction of the support plate) of the heating lines (300a, 300b, and 300c) of the heating portion 300 may increase as a distance to the center of the heating portion 300 decreases. That is, a heating line 300a arranged at the center of the heating portion 300 may have a greater thickness than a heating line 300c arranged at an edge of the heating portion 300. The area of the heating lines (300a, 300b, and 300c) may increase as a distance to the center of the heating portion 300 decreases, thus emitting a greater amount of heat. The amount of heat generated by the heating portion 300 may increase as a distance to the center of the heating portion 300 decreases. That is, the heating lines (300a, 300b, and 300c) of the heating portion 300 may emit different amounts of heat according to a part of the heating portion 300.

In some embodiments, a thickness T_200 of the insulating layer 200 may be about 40 μm to about 200 μm. In some embodiments, the insulating layer 200 may include four to six layers each having a thickness of about 10 μm.

In some embodiments, the withstand voltage of the insulating layer 200 may be about 1.5 kv to about 5 kv. That is, the insulating layer 200 may have a withstand of about 1.5 kv to about 5 kv at a thickness of about 40 μm to about 200 μm. As the insulating layer 200 has a multi-layer structure and high current resistance, the withstand voltage at the same thickness may be high.

In the trend towards a thickness of the support plate 100 less than or equal to 4 mm, controlling the physical deformation of the support plate 100 (e.g., bending) may be required in the process of forming the insulating layer 200. The substrate heater 1100 according to an embodiment may include the insulating layer 200 including a plurality of layers (201 and 202) having different CTEs from each other. In the process of forming materials having different CTEs from each other under the support plate 100, bending of the support plate 100 may be suppressed by mutual complementation among the materials having different CTEs from each other.

More specifically, by forming a material having a greater CTE than the support plate 100 first, and then forming a material having a smaller CTE than the support plate 100, bending of the support plate 100 may be suppressed. In some embodiments, the bending of the support plate 100 caused during the formation of the first layer 201 under the support plate 100 may be offset by the bending of the support plate 100 caused during the formation of the second layer 202, and ultimately, the bending of the support plate 100 may be suppressed.

The support plate 100 may be configured to be loaded with the substrate W and heat up the substrate W. The more the support plate 100 departs from a designed shape, the lower the quality of the substrate processing may become. As the substrate heater (1100 and 1100′) according to an embodiment suppresses physical deformation of the support plate 100 and improves flatness of the support plate 100, the quality of the substrate processing may be enhanced.

The substrate heater (1100 and 1100′) according to an embodiment may include the insulating layer 200 having a multi-layer structure. The insulating layer 200 of multi-layer structure may have a higher withstand voltage than an insulating layer of single-layer structure. That is, due to characteristics of the multi-layer structure, insulation of the insulating layer 200 may be improved.

FIG. 4 is a schematic cross-sectional view of a substrate heater according to an embodiment.

Referring to FIG. 4, a substrate heater 1100a may include a support plate 100a, an insulating layer 200, and a heating portion 300.

Hereinafter, any redundant descriptions on the substrate heater 1100a of FIG. 4 and the substrate heater 1100 of FIG. 1A are omitted, and embodiments will be described focusing on the differences.

The support plate 100a of the substrate heater 1100a may further include an oxide layer 101 thereunder. That is, the oxide layer 101 may be arranged between a lower surface of the support plate 100a and the insulating layer 200. The oxide layer 101 may be formed through an oxidation process performed on the support plate 100a, and the oxide layer 101 may be formed to cover the lower surface of the support plate 100a. For example, the oxide layer 101 may include silicon oxide.

In some embodiments, each of a plurality of layers (201 and 202) of the insulating layer 200 may include paste as a constituent material. The paste may include a silicon oxide or an aluminum oxide. That is, a main component of the paste may be a silicon oxide or an aluminum oxide, and an accessory component may include filler. A CTE of each layer may be adjusted by the concentration of the filler.

The oxide layer 101 of the substrate heater 1100a according to an embodiment may be arranged between the support plate 100a and the insulating layer 200. The insulating layer 200 may include an oxide such as a silicon oxide, an aluminum oxide, etc. The oxide included in the insulating layer 200, such as a silicon oxide or an aluminum oxide may have a great bonding strength to the oxide layer 101. That is, the bonding strength among oxides may be high. Due to the high bonding strength between the insulating layer 200 and the oxide layer 101, isolation of the insulating layer 200 from the support plate 100a may be suppressed.

FIG. 5 is a schematic cross-sectional view of a substrate heater according to an embodiment.

Referring to FIG. 5, a substrate heater 1100b may include a support plate 100b, an insulating layer 200, and a heating portion 300.

Hereinafter, any redundant descriptions on the substrate heater 1100b of FIG. 5 and the substrate heater 1100 of FIG. 1 are omitted, and embodiments will be described focusing on the differences.

An upper surface 100b_U of the support plate 100b of the substrate heater 1100b may be a curved surface. More specifically, a lower surface 100b_L of the support plate 100b may be a flat surface, and the upper surface 100b_U of the support plate 100b may be a curved surface which becomes closer to the lower surface 100b_L at an edge of the support plate 100b. In the support plate 100b, a central portion and an edge portion may have different thicknesses from each other.

That is, the thickness at the central portion of the support plate 100b may be greater than the thickness at the edge portion. In other words, the thickness of the support plate 100b may increase as a distance to the center of the upper surface 100b_U of the support plate 100b decreases. In other words, in a cross-sectional view, the upper surface 100b_U of the support plate 100b may have a convex shape of which center is protruded upwards from the edge.

In some embodiments, the upper surface 100b_U and the lower surface 100b_L of the support plate 100b may be a curved surface. The support plate 100b may have an upwardly convex shape. In other words, the centers of the upper surface 100b_U and the lower surface 100b_L of the support plate 100b may be upwardly convex. In this regard, the upper surface 100b_U and the lower surface 100b_L may have the same curvature, and the support plate 100b may have the same thickness at every areas.

In the substrate heater 1100b according to an embodiment, a distance between the support plate 100b and the substrate W may vary. In other words, the distance between the support plate 100b and the substrate W in the central area of the support plate 100b may be short. The less the distance between the support plate 100b and the substrate W is, the easier the heat of the support plate 100b may be transmitted to the substrate W. Accordingly by adjusting the distance between the support plate 100b and the substrate W by area of the support plate 100b, the quality of the substrate processing may be enhanced.

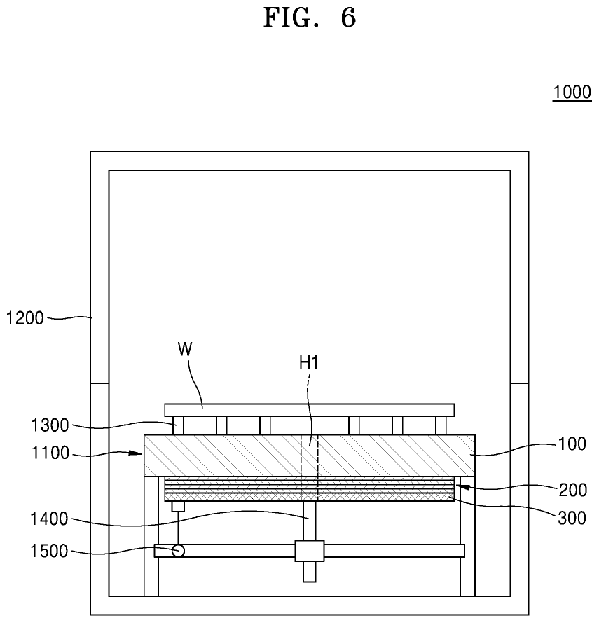

FIG. 6 is a schematic cross-sectional view of a substrate processing apparatus according to an embodiment.

Referring to FIG. 6, a substrate processing apparatus 1000 may include a chamber 1200, the substrate heater 1100, a support pin 1300, a lifting pin 1400, and a power source 1500.

The chamber 1200 of the substrate processing apparatus 1000 may provide therein a processing space in which the substrate W is processed. For example, the chamber 1200 may have a cylindrical shape. The processing space may be sealed from the outside of the chamber 1200 by an upper wall and a side wall of the chamber 1200.

Although it is not specifically illustrated in the drawings, the chamber 1200 may include an exhaust hole at its lower portion. The exhaust hole may be connected to an exhaust line with a pump. The exhaust hole may discharge reaction byproducts generated in a photo process and a residual gas inside the chamber 1200 to the outside of the chamber 1200 through the exhaust line. In this case, the inner space of the chamber 1200 may be decompressed to a certain pressure.

The substrate W may be mounted on the substrate heater 1100 of the substrate processing apparatus 1000. The substrate heater 1100 may have a through hole H1 extending from an upper surface to a lower surface of the substrate heater 1100. The substrate heater 1100 may include the support plate 100, the insulating layer 200, and the heating portion 300.

In some embodiments, the insulating layer 200 of the substrate heater 1100 may include a first layer and a second layer, which are alternately stacked. The first layer may have a CTE greater than the CTE of the support plate 100, and the second layer may have a CTE less than the CTE of the support plate 100. The first layer may be in contact with the support plate 100, and the second layer may be in contact with the heating portion 300. However, the order of the first layer and the second layer is not limited thereto. The second layer may be in contact with the support plate 100, and the first layer may be in contact with the heating portion 300.

In some embodiments, the insulating layer 200 may include a plurality of stacked layers including a first layer, a second layer, and a third layer. The first layer may have a CTE greater than the CTE of the support plate 100, the second layer may have a CTE less than the CTE of the support plate 100, and the third layer may have a CTE identical to the CTE of the support plate 100. That is, the CTE may be divided into three areas based on the CTE of the support plate 100, and the insulating layer 200 may include three layers which have different areas of CTE from each other.

In some embodiments, the thickness of the insulating layer 200 may be about 40 μm to about 200 μm, and the withstand voltage of the insulating layer 200 may be about 1.5 kV to about 5 kV. The thickness of each layer of the insulating layer 200 may be about 10 μm to about 15 μm.

In some embodiments, the substrate heater 1100 may include the substrate heater (1100 of FIG. 1A, 1100′ of FIG. 1B, 1100a of FIG. 4, and 1100b of FIG. 5) described in relation to FIGS. 1A to 5.

The support pin 1300 of the substrate processing apparatus 1000 may be arranged on the upper surface of the substrate heater 1100. The substrate W may be mounted on the support pin 1300. That is, the support pin 1300 may be arranged on the upper surface of the substrate heater 1100, and the substrate W may be placed on the substrate heater 1100. In other words, the substrate W may be apart from the upper surface of the substrate heater 1100 with the support pin 1300 arranged therebetween.

A cross-section of an area of the support pin 1300 that supports the substrate W may have a polygonal shape such as a circular shape or a rectangular shape. The support pins 1300 may have the same height. That is, the support pin 1300 may support the substrate W without tilting of the substrate W towards one side.

The lifting pin 1400 of the substrate processing apparatus 1000 may lift and lower the substrate W. The lifting pin 1400 may pass through the through hole H1. That is, the width of the lifting pin 1400 may be less than the width of the through hole H1, and the lifting pin 1400 may move inside the through hole H1.

The lifting pin 1400 may move vertically and be in contact with the lower surface of the substrate W. That is, the lifting pin 1400 may move upward to lift the substrate W. The lifting pin 1400 may move downward to lower the substrate W such that the substrate W is placed on the support pin 1300. That is, the lifting pin 1400 may lift and lower the substrate W during the process of mounting the substrate W on the substrate heater 1100.

The power source 1500 of the substrate processing apparatus 1000 may be connected to the substrate heater 1100. More specifically, the power source 1500 may be connected to the heating portion 300 of the substrate heater 1100. In some embodiments, the power source 1500 may supply power to the heating portion 300, and the heating portion 300 may emit heat. In some embodiments, the power source 1500 may be connected to an electrode pad of the heating portion 300.

In the substrate processing apparatus 1000 according to an embodiment, physical deformation of the support plate 100 during the process of manufacturing the substrate heater 1100 may be suppressed, and the support plate 100 may be maintained in the designed shape. Accordingly, the temperature uniformity of the substrate W during a substrate baking process may be improved. Ultimately, the quality of the substrate processing may be improved.

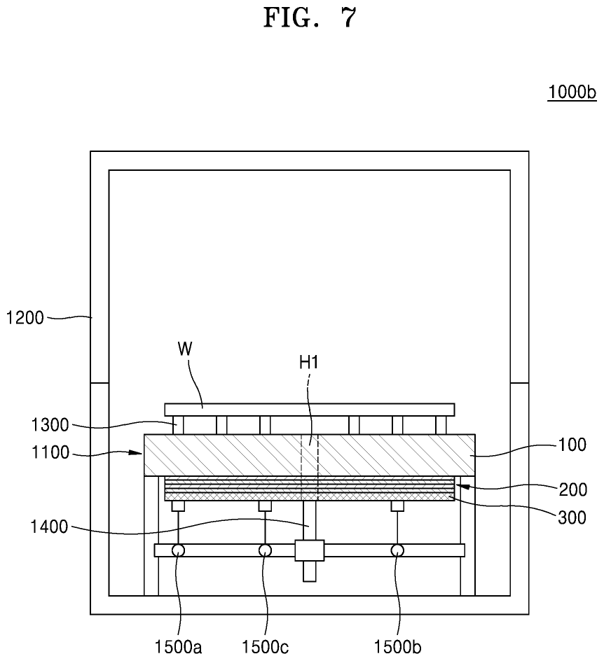

FIG. 7 is a schematic cross-sectional view of a substrate processing apparatus according to an embodiment.

Referring to FIG. 7, a substrate processing apparatus 1000a may include a chamber 1200, the substrate heater 1100, a support pin 1300, a lifting pin 1400, and a plurality of power sources (1500a, 1500b, and 1500c). Hereinafter, any redundant descriptions on the substrate processing apparatus 1000a of FIG. 7 and the substrate processing apparatus 1000 of FIG. 6 are omitted, and embodiments will be described focusing on the differences.

The substrate heater 1100 of the substrate processing apparatus 1000a may include the heating portion 300, and the heating portion 300 may be arranged under the substrate heater 1100. The heating portion 300 may include a heating line generating heat. The heating portion 300 may generate heat by using the heating line and heat the support plate 100.

As described above in relation to FIG. 3, the heating lines of the heating portion 300 may be arranged in a structure of multiple concentric circles. In some embodiments, the concentric circles may have different widths from each other. The closer the heating line is to the center of the heating portion 300, the greater the width of the heating line may be. Or, the plurality of concentric circles may have the same width and each of the plurality of concentric circles may be connected to one of a plurality of power sources.

The plurality of power sources (1500a, 1500b, and 1500c) of the substrate processing apparatus 1000a may be connected to different heating lines from each other. That is, the plurality of power sources (1500a, 1500b, and 1500c) may respectively be connected to heating lines arranged in different areas of the heating line 300 from each other. In some embodiments, a first power source 1500a may be connected to a heating line arranged in an edge area of the heating portion 300. A second power source 1500c may be connected to a heating line arranged in a central area of the heating portion 300. A third power source 1500b may be connected to a heating line arranged between the edge area and the central area of the heating portion 300.

In some embodiments, the first power source 1500a to the third power source 1500b may provide power of different intensities from each other. That is, the first power source 1500a to the third power source 1500b may transmit different amounts of current to the heating lines. In some embodiments, the intensity of the power provided by the first power source 1500a may be less than the intensity of the power provided by the second power source 1500c, and the intensity of the power provided by the third power source 1500b may be between the intensity of the power of the first power source 1500a and the intensity of the power of the second power source 1500c.

That is, as the intensities of power provided by the first power source 1500a to the third power source 1500b are different from each other, the amounts of heat emitted by the heating lines respectively connected to the power sources may be different from each other. When the amount of current provided to the heating line increases, the amount of heat emitted from the heating line may increase as well. In some embodiments, the closer the heating line is to the center of the heating portion 300, the more the power is provided to the heating, and thus, the heating portion 300 may emit more heat at the central area than at the edge area.

In some embodiments, the substrate processing apparatus 1000a may adjust the heat emission amount of each area of the heating portion 300 by using the plurality of power sources (1500a, 1500b, and 1500c). Accordingly, in the process of baking the substrate, the temperature of the substrate W may be adjusted and controlled by area, high-quality substrate processing may be performed.

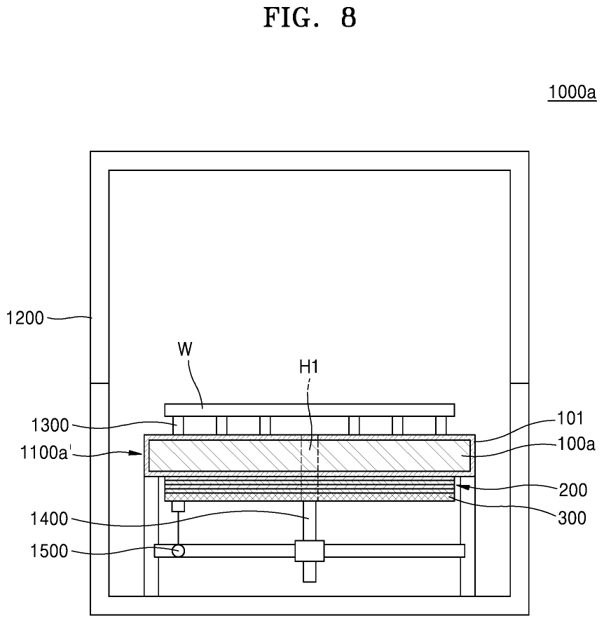

FIG. 8 is a schematic cross-sectional view of a substrate processing apparatus according to an embodiment.

Referring to FIG. 8, a substrate processing apparatus 1000b may include a chamber 1200, a substrate heater 1100a′, a support pin 1300, a lifting pin 1400, and a power source 1500. Hereinafter, any redundant descriptions on the substrate processing apparatus 1000b of FIG. 8 and the substrate processing apparatus 1000 of FIG. 6 are omitted, and embodiments will be described focusing on the differences.

The substrate heater 1100a′ of the substrate processing apparatus 1000b may include the support plate 100a, the insulating layer 200, the heating portion 300, and the oxide layer 101. The oxide layer 101 of the substrate heater 1100a′ may be arranged between the insulating layer 200 and the support plate 100a. The oxide layer 101 may be formed by oxidizing the surface of the support plate 100a. That is, the oxide layer 101 may be formed on the surface of the support plate 100a and may be arranged on all surfaces of the support plate 100a.

In some embodiments, the support plate 100a may include silicon carbide, and the oxide layer 101 may include silicon oxide. The insulating layer 200 may include an oxide such as a silicon oxide, an aluminum oxide, etc. Due to high bonding strength between the oxides, the bonding strength between the insulating layer 200 and the oxide layer 101 may be high. That is, the bonding strength between the insulating layer 200 and the oxide layer 101 formed on the lower surface of the support plate 100a may be high. Accordingly, isolation of the insulating layer 200 from the support plate 100 may be suppressed.

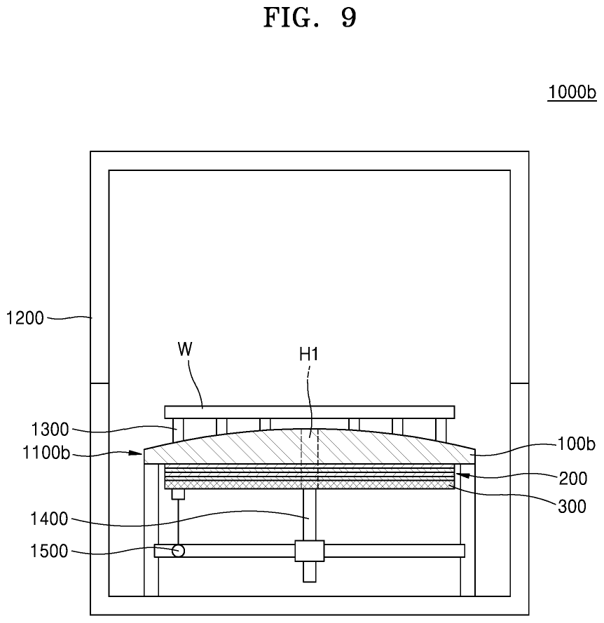

FIG. 9 is a schematic cross-sectional view of a substrate processing apparatus according to an embodiment.

Referring to FIG. 9, a substrate processing apparatus 1000c may include the chamber 1200, the substrate heater 1100b, the support pin 1300, the lifting pin 1400, and the power source 1500. Hereinafter, any redundant descriptions on the substrate processing apparatus 1000c of FIG. 9 and the substrate processing apparatus 1000 of FIG. 6 are omitted, and embodiments will be described focusing on the differences.

The substrate heater 1100b of the substrate processing apparatus 1000c may include the support plate 100b, the insulating layer 200, and the heating portion 300. The upper surface of the support plate 100b may be a curved surface. That is, a space between the support plate 100b and the substrate W may vary by area of the support plate 100b. In some embodiments, the less the distance to the center of the upper surface of the support plate 100b is, the less the distance between the support plate 100b and the substrate W may be.

More specifically, the lower surface of the support plate 100b may be a flat surface, and the upper surface of the support plate 100b may be a curved surface which becomes closer to the lower surface 100b_L at an edge of the support plate 100b. In the support plate 100b, a central portion and an edge portion may have different thicknesses from each other. That is, the thickness at the central portion of the support plate 100b may be greater than the thickness at the edge portion. In other words, the thickness of the support plate 100b may increase as a distance to the center of the upper surface 100b_U of the support plate 100b decreases.

In the substrate processing apparatus 1000b according to an embodiment, a distance between the support plate 100b and the substrate W may vary. In other words, the distance between the support plate 100b and the substrate W in the central area of the support plate 100b may be short. The less the distance between the support plate 100b and the substrate W is, the easier the heat of the support plate 100b may be transmitted to the substrate W. Accordingly by adjusting the distance between the support plate 100b and the substrate W by area of the support plate 100b, the quality of the substrate processing may be enhanced.

FIGS. 10A to 10G are cross-sectional views schematically illustrating a manufacturing method of a substrate heater according to an embodiment.

A method of manufacturing a substrate heater including an insulating layer consisting of four layers is described by referring to FIGS. 10A to 10G.

FIG. 10A illustrates arranging a lower surface 100_L of the support plate 100 to face upward. The support plate 100 may include the through hole H1. The through hole H1 may extend from an upper surface 100_U of the support plate 100 to the lower surface 100_L. A material constituting the support plate 100 may include silicon carbide. The support plate 100 may include a semiconductor material. The thickness T_100 of the support plate 100 may be about 0.5 mm to about 3 mm. That is, the thickness T_100 of the support plate 100 may not exceed 4 mm.

FIG. 10B illustrates forming the first layer 201 of the insulating layer on the lower surface 100_L of the support plate 100. The first layer 201 may be a paste material having a greater CTE than the support plate 100. That is, the paste including silicon oxide and filler may be sprayed on the support plate 100.

In some embodiments, the first layer 201 may be sprayed in a patterned shape corresponding to the through hole of the support plate. In some embodiments, the thickness T_201 of the first layer 201 may be about 10 μm to about 25 μm. In some embodiments, the upper surface 100_U of the support plate 100 may be a curved surface. In some embodiments, the support plate 100 may be oxidized, and further include an oxide layer on its surface.

FIG. 10C illustrate heating the first layer 201 and the support plate 100. The first layer 201 in the paste state may be phase-changed to a solid state through heating and cooling. In the process of heating the first layer 201 and the support plate 100, the length and the volume of the first layer 201 and the support plate 100 may be changed according to the temperature change.

More specifically, when the CTE of the first layer 201 is greater than the CTE of the support plate 100, the volume change of the first layer 201 according to the temperature change may be greater than the volume change of the support plate 100 according to the temperature change. As the temperature change of the first layer 201 and the support plate 100 during the heating process is substantially identical to each other, the volume change of the first layer 201 is greater than that of the support plate 100.

However, as the first layer 201 is in contact with the support plate 100, an end portion of the first layer 201 may be bent towards the support plate 100. That is, an end portion of a material layer having a great CTE may be bent towards a material layer having a small CTE. In other words, the first layer 201 and the support plate 100 may become a upwardly convex shape during the heating process.

FIG. 10D illustrates forming the second layer 202 on the first layer 201. The second layer 202 may be a paste material having a CTE less than the CTE of the support plate 100. That is, the paste including silicon oxide and filler may be sprayed to the first layer that is bent upwards.

In some embodiments, the second layer 202 may be sprayed in a patterned shape corresponding to the pattern of the support plate 100 and the first layer 201. In some embodiments, the thickness T_202 of the second layer 202 may be about 10 μm to about 25 μm. In some embodiments, the first layer 201 and the second layer 202 may have different CTEs from each other. As the amounts of the filler included in the first layer 201 and the second layer 202 are different from each other, the CTEs thereof may be different from each other.

FIG. 10E illustrates heating the first layer 201, the second layer 202, and the support plate 100. The second layer 202 in the paste state may be phase-changed to a solid state through heating and cooling. During the process of heating the first layer 201, the second layer 202, and the support plate 100, the length and the volume of the first layer 201, the second layer 202, and the support plate 100 may be changed according to the temperature change.

More specifically, when the CTE of the second layer 202 is less than the CTE of the first layer 201 and the CTE of the support plate 100, the volume change of the second layer 202 according to the temperature change may be less than those of the first layer 201 and the support plate 100. During the heating process, as the same temperature change occurs to the first layer 201 and the second layer 202, and the support plate 100, the volume change of the second layer 202 may be the least.

However, as the second layer 202 is in contact with the first layer 201, the end portions of the first layer 201 and the support plate 100 having a great CTE may be bent towards the second layer 202. In other words, the support plate 100 having an upwardly convex shape may be transformed to a flat shape having no curvature through the heating process. That is, by sequentially forming the first layer 201 and the second layer 202 which have different CTEs from each other, physical deformation of the support plate 100 may be suppressed.

FIG. 10F illustrates alternately stacking the first layer 201 and the second layer 202 and forming the insulating layer 200 including a plurality of layers. That is, a plurality of layers may be formed by repeating the processes of FIGS. 10B to 10E. In some embodiments, the number of the first layers 201 may be identical to the number of the second layers 202. The bending of the support plate 100 caused during the formation of the first layer 201 may be offset during the formation of the second layers 202. Accordingly, by forming the same numbers of first layers 201 and the second layers 202, physical deformation of the support plate 100 may be suppressed.

FIG. 10G illustrates forming the heating portion 300 on the insulating layer 200. That is, the heating portion 300 may be apart from the support plate 100 with the insulating layer 200 therebetween.

In some embodiments, the heating portion 300 may include a heating line. That is, a patterned heating line may be printed on the insulating layer 200. The area or width of the patterned heating line may vary according to a distance to the center of the insulating layer 200.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate heater comprising:
a support plate configured to be loaded with a substrate;
an insulating layer arranged under the support plate; and
a heating portion arranged under the insulating layer and configured to heat the support plate,
wherein the insulating layer includes a plurality of layers, and
at least two of the plurality of layers of the insulating layer have different thermal expansion coefficients from each other.

2. The substrate heater of claim 1, wherein a first layer and a second layer of the insulating layer are stacked alternately, and
a thermal expansion coefficient of the first layer and a thermal expansion coefficient of the second layer are different from a thermal expansion coefficient of the support plate.

3. The substrate heater of claim 2, wherein the insulating layer includes an even number of layers.

4. The substrate heater of claim 2, wherein the thermal expansion coefficient of the first layer is greater than the thermal expansion coefficient of the support plate, and
the thermal expansion coefficient of the second layer is less than the thermal expansion coefficient of the support plate.

5. The substrate heater of claim 2, wherein the thermal expansion coefficient of the first layer is about 4.5e⁻⁶/° C. to about 8.5e⁻⁶/° C., and the thermal expansion coefficient of the second layer is about 2.5e⁻⁶/° C. to about 3.5e⁻⁶/° C.

6. The substrate heater of claim 1, wherein an average thermal expansion coefficient of the insulating layer is identical to a thermal expansion coefficient of the support plate.

7. The substrate heater of claim 1, wherein a thickness of the insulating layer is about 40 μm to about 200 μm.

8. The substrate heater of claim 1, wherein a withstand voltage of the insulating layer is about 1.5 kV to about 5 kV.

9. The substrate heater of claim 1, wherein a thickness of each of the plurality of layers of the insulating layer is about 10 μm to about 25 μm.

10. The substrate heater of claim 1, wherein a thickness of the support plate is about 0.5 mm to about 3 mm.

11. The substrate heater of claim 1, wherein the support plate further includes an oxide layer on a lower surface thereof.

12. The substrate heater of claim 1, wherein the insulating layer includes a first layer, a second layer, and a third layer,
a thermal expansion coefficient of the first layer is greater than a thermal expansion coefficient of the support plate,
a thermal expansion coefficient of the second layer is less than the thermal expansion coefficient of the support plate, and
a thermal expansion coefficient of the third layer is less than the thermal expansion coefficient of the first layer and is greater than the thermal expansion coefficient of the second layer.

13. A substrate processing apparatus comprising:
a chamber;
a substrate heater arranged in the chamber, having a through hole extending from an upper surface to a lower surface thereof, and including a support plate, an insulating layer, and a heating portion;
a support pin arranged on an upper surface of the support plate and configured to support a substrate;
a lifting pin configured to lift and lower the substrate through the through hole; and
at least one power source connected to the substrate heater,
wherein the insulating layer is arranged under the support plate and includes a plurality of layers,
at least two of the plurality of layers have different thermal expansion coefficients from each other, and
the heating portion is arranged under the insulating layer.

14. The substrate processing apparatus of claim 13, wherein the heating portion includes a plurality of heating lines on an upper surface thereof,
the plurality of heating lines are respectively connected to different power sources from each other, and
an intensity of power of the power sources increases as a distance between the plurality of heating lines respectively connected to the power sources and a center of the heating portion decreases.

15. The substrate processing apparatus of claim 13, wherein a lower surface of the support plate is a flat surface, and
the upper surface of the support plate is an upwardly convex curved surface.

16. The substrate processing apparatus of claim 13, wherein, in the insulating layer, a first layer having a thermal expansion coefficient greater than a thermal expansion coefficient of the support plate and a second layer having a thermal expansion coefficient less than the thermal expansion coefficient of the support layer are alternately stacked,
at least a part of the first layer is in contact with the support plate, and
at least a part of the second layer is in contact with the heating portion.

17. The substrate processing apparatus of claim 13, wherein a thickness of the insulating layer is about 40 μm to about 200 μm, and
a withstand voltage of the insulating layer is about 1.5 kV to about 5 kV.

18. The substrate processing apparatus of claim 13, wherein a first layer, a second layer, and a third layer of the insulating layer are stacked alternately,
a thermal expansion coefficient of the first layer is greater than a thermal expansion coefficient of the support plate,
a thermal expansion coefficient of the second layer is less than the thermal expansion coefficient of the support plate, and
a thermal expansion coefficient of the third layer is identical to the thermal expansion coefficient of the support plate.

19. The substrate processing apparatus of claim 13, wherein the substrate heater further includes an oxide layer between the support plate and the insulating layer.

20. A substrate processing apparatus comprising:
a chamber;
a substrate heater arranged in the chamber, having a through hole extending from an upper surface to a lower surface thereof, and including a support plate, an insulating layer, and a heating portion;
a support pin arranged on an upper surface of the support plate and configured to support a substrate;
a lifting pin configured to lift and lower the substrate through the through hole; and
at least one power source arranged in the chamber and connected to the substrate heater,
wherein the support plate includes silicon carbide,
the insulating layer is arranged under the support plate and incudes an even number of layers, wherein a first layer having a thermal expansion coefficient greater than a thermal expansion coefficient of the support plate and a second layer having a thermal expansion coefficient less than the thermal expansion coefficient of the support layer are alternately stacked,
a thickness of the first layer is about 10 μm to about 25 μm, and a thickness of the second layer is about 10 μm to about 25 μm.
